(19) United States
(12) Patent Application Publication
(10) Pub. No.: US 2016/0053377 A1
(43) Pub. Date: Feb. 25, 2016

(54) SUBSTRATE PROCESSING APPARATUS, METHOD OF MANUFACTURING SEMICONDUCTOR DEVICE, AND SUBSTRATE PROCESSING METHOD

(71) Applicant: HITACHI KOKU SAI ELECTRIC INC., Tokyo (JP)

(72) Inventor: Tomoshi TANIYAMA, Toyama-shi (JP)

(73) Assignee: HITACHI KOKUSAI ELECTRIC INC., Tokyo (JP)

(21) Appl. No.: 14/779,729

(22) PCT Filed: Mar. 24, 2014
(86) PCT No.: PCT/JP2014/058053

§ 371 Date: Sep. 24, 2015

(30) Foreign Application Priority Data
Mar. 25, 2013 (JP) 2013-061832

(51) Int. Cl. C23C 16/52; H01L 21/02; C23C 16/44

(52) U.S. Cl. CPC C23C 16/52; C23C 16/4412; H01L 21/02271; H01L 21/02186

(57) ABSTRACT

With the miniaturization of semiconductors and the increase in the diameter of wafers, the wafer size increases. Therefore, a supply gas flow rate also increases as compared with a process of a conventional wafer size. Thus, it is difficult to perform an exhaust pressure control in the same manner as a conventional processing process. ON/OFF valves provided in a plurality of exhaust pipes communicating with a processing chamber and a vacuum pump, and a controller configured to control the ON/OFF valves are provided, and it is possible to cope with the increase in the diameter of the wafer by performing a valve on/off and pressure control operation in a process event.

### FIELD OF THE INVENTION

The present invention relates to a substrate processing apparatus, a method of manufacturing a semiconductor device, and a substrate processing method.

### DESCRIPTION OF THE RELATED ART

With the miniaturization of semiconductors and the increase in the diameter of wafers, the volume of a semiconductor device housing has become large. Therefore, a supply gas flow rate increases as compared with a conventional processing process. Thus, it is difficult to perform an exhaust pressure control in the same manner as a conventional processing process. In order to avoid this, it is essential to increase an amount of exhaust. In order to increase the amount of exhaust, it is necessary to make an exhaust pipe thick and reduce conductance. A main valve is disposed near a reaction chamber so as to shorten a pipe as much as possible. However, if a valve or a pipe is simply made thick, a pipe is laid out in an outer side than a width of a substrate processing apparatus, thus increasing a footprint of the apparatus.

FIG. 7 illustrates a conventional exhaust system. Pipes 704a and 704b are connected to a pump 703 through a main valve (pressure control valve: APC) 702 disposed at a position closest to a reaction chamber 701. In a conventional processing process, a supply gas flow rate and a pressure control are possible in this system. However, due to an increase in a diameter of a wafer, a flow rate in a process of processing a semiconductor device is increased about 1.5 times as compared with a conventional processing process. Therefore, in order to perform a pressure control, it is necessary to increase a diameter of a pipe (see FIG. 8). A layout of a conventional apparatus is illustrated in FIG. 8. A reaction chamber 701 and an APC 702 are connected through a pipe 704 and are laid out not to come out from a lateral width of the substrate processing apparatus. However, if the diameter of the pipe 704 or the APC 702 increases, the pipe 704 or the APC 702 is disposed to greatly come out from the lateral width of the substrate processing apparatus as illustrated in the layout of FIG. 8. Therefore, there is a problem that the footprint increases.

### SUMMARY OF THE INVENTION

### Technical Problem

The present invention is directed to provide a substrate processing apparatus, a method of manufacturing a semiconductor device, and a substrate processing method, which solve a problem that it is difficult to perform the same exhaust pressure control as the conventional art when a supply gas flow rate is increased by an increase in a volume of a reaction tube due to an increase in a diameter of a substrate to be processed.

### Solution to Problem

In order to achieve the above object, a substrate processing apparatus according to the present invention is a substrate processing apparatus, including: a reaction tube configured to process substrates by carrying in a substrate holder holding a plurality of substrates; a gas supply unit configured to supply a processing gas into the reaction tube; an exhaust unit including at least two exhaust pipes configured to exhaust gas supplied by the gas supply unit, and valves provided in the at least two exhaust pipes to control exhaust amount of the at least two exhaust pipes; and a control unit configured to control the valves provided in the exhaust unit at a predetermined timing.

Furthermore, a method of manufacturing a semiconductor device includes: carrying in a substrate holder holding a plurality of substrates into a reaction tube; supplying a processing gas from a gas supply unit into the reaction tube; after the process of supplying the processing gas, exhausting the processing gas by an exhaust unit, the exhaust unit including at least two exhaust pipes and at least two valves provided in the at least two exhaust pipes so as to control exhaust amount of the at least two exhaust pipes; and controlling the at least two valves provided in the exhaust unit at a predetermined timing.

Furthermore, a substrate processing method includes: carrying in a substrate holder holding a plurality of substrates into a reaction tube; supplying a processing gas from a gas supply unit into the reaction tube; and after the process of supplying the processing gas, controlling at least two exhaust pipes and at least two valves so as to adjust exhaust amount of the exhaust pipes.

### Advantageous Effects of Invention

According to the present invention, it is possible to provide a substrate processing apparatus, a method of manufacturing a semiconductor device, and a substrate processing method, which are capable of performing an exhaust pressure control of a processing gas through a simple configuration in association with an increase in a diameter of a substrate to be processed.

### BRIEF DESCRIPTION OF THE DRAWINGS

FIG. 1 is a perspective view of a substrate processing apparatus that is applied to the present invention.

FIG. 2 is a side perspective view of the substrate processing apparatus that is applied to the present invention.

FIG. 3 is a diagram illustrating a configuration of a controller of the substrate processing apparatus to which the present invention is applied.

FIG. 4 is a schematic longitudinal sectional view of a substrate processing apparatus according to an embodiment of the present invention.

FIG. 5 is a schematic horizontal sectional view of a substrate processing apparatus according to an embodiment of the present invention.

FIG. 6 is a diagram illustrating an example of a process event according to an embodiment of the present invention.

FIG. 7 is a schematic longitudinal sectional view of a substrate processing apparatus according to the related art.

FIG. 8 is a schematic horizontal sectional view of a substrate processing apparatus, so as to describe the related art.

### DETAILED DESCRIPTION OF THE PREFERRED EMBODIMENTS

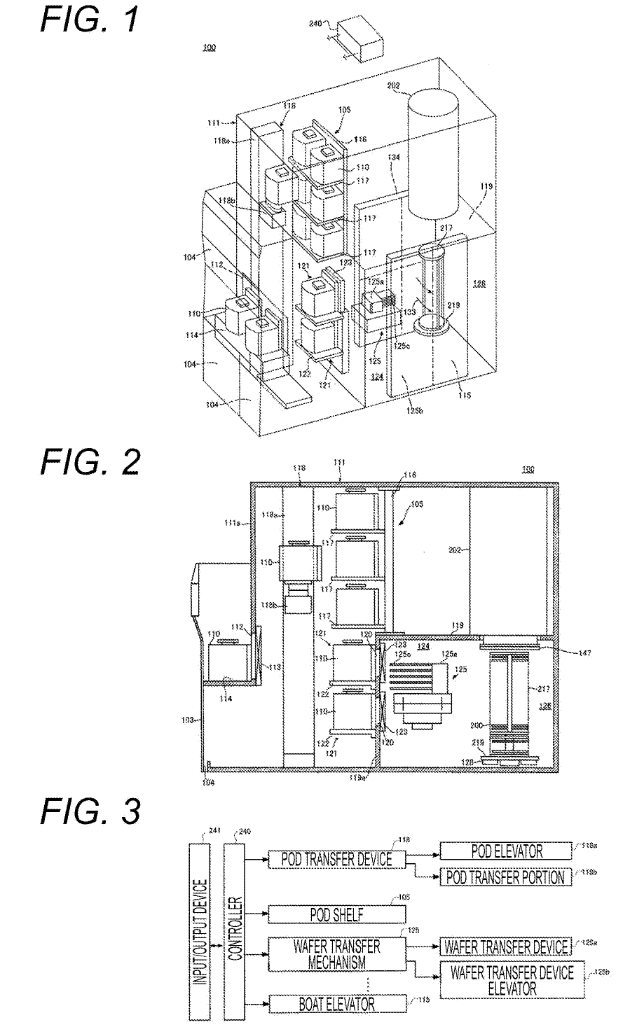

First, a vertical heat treatment apparatus, which uses an example of the present invention, will be described with reference to FIGS. 1 and 2. A substrate processing apparatus of FIGS. 1 and 2 is diagrams for describing a configuration of a semiconductor manufacturing apparatus that performs a processing process in a method of manufacturing a semiconductor device (IC). As a substrate processing apparatus, a case where a vertical heat treatment apparatus (hereinafter, simply referred to as a processing apparatus) performing oxidation, a diffusion process, a CVD process, or the like on a substrate is applied will be described below. FIG. 1 is a perspective view of a processing apparatus that is applied to the present invention. Also, FIG. 2 is a side perspective view of the processing apparatus illustrated in FIG. 1.

As illustrated in FIGS. 1 and 2, the processing apparatus 101 of the present invention includes a housing 111 as a substrate processing apparatus body, which uses a FOUP (also called a cassette or a pod, and hereinafter referred to as a pod) 110 as a wafer carrier that accommodates a plurality of wafers (substrates) 200 made of silicon or the like and is used as a storage container. The wafers 200 are transferred in a state of being charged and sealed in the pod 110.

As a port disposed to be maintenance-possible, a front maintenance port 103 is disposed in a front anterior portion of a front wall 111a of the housing 111. A front maintenance door 104 is provided so as to open and close the front maintenance port 103. In the maintenance door 104, a pod carrying-in/carrying-out port 112 is disposed to communicate with the inside and the outside of the housing 111. The pod carrying-in/carrying-out port 112 is opened and closed by a front shutter 113. In a front anterior side of the pod carrying-in/carrying-out port 112, a load port 114 used as a carrying-in/carrying-out portion is provided. The load port 114 is configured such that the pod 110 is placed and aligned. The pod 110 is carried in to the load port 114 and is carried out from the load port 114 by an in-process transfer device (not illustrated).

In an upper portion of a substantially central part of the housing 111 in a front-back direction, a pod shelf (housing shelf) 105 is provided. The pod shelf 105 is configured to store a plurality of pods 110 at multiple stages along multiple rows. The pod shelf 105 includes a support portion 116 which is vertically erected, and multi-stage placement portions 117 which are held to be independently movable in a vertical direction at each position of the upper, middle, and lower stages with respect to the support portion 116. The pod shelf 105 is configured to hold a plurality of pods 110 in a state of being placed in the multi-stage placement portions 117. That is, the pod shelf 105 accommodates a plurality of pods 110 at multiple stages in a vertical direction, for example, by placing two pods 110 to face the same direction on a straight line.

A pod transfer device (accommodation container transfer mechanism) 118 is installed between the load port 114 and the pod shelf 105 in the housing 111. The pod transfer device 118 includes a pod elevator 118a as an a shaft portion which is vertically movable while holding the pods 110, and a pod transfer portion 118b as a transfer portion which transfers the pods 110 placed thereon in a horizontal direction. The pod transfer device 118 is configured to transfer the pods 110 among the load port 114, the pod shelf 105, and a pod opener 121 by a continuous operation of the pod elevator 118a and the pod transfer portion 118b.

In a lower portion of the substantially central part of the housing 111 in a front-back direction, a sub-housing 119 is built up over a rear end. A pair of wafer carrying-in/carrying-out ports 120 for carrying in and out the wafer 200 with respect to the sub-housing 119 is provided to be opened in a two-upper/lower-stage alignment in a vertical direction in a front wall 119a of the sub-housing 119, and a pair of pod openers 121 and 121 is provided at two-upper/lower-stage wafer carrying-in/carrying-out ports 120 and 120. The pod opener 121 includes placement tables 122 and 122 on which the pod 110 is placed, and cap attaching/detaching mechanisms 123 and 123 which attach and detach a cap of the pod 110 that is used as a sealing member. The pod opener 121 is configured to open and close a wafer loading/unloading port of the pod 110 by attaching and detaching the cap of the pod 110 placed on the placement table 122 by the cap attaching/detaching mechanism 123.

The sub-housing 119 constitutes a transfer chamber 124 that is fluidically isolated from an installation space of the pod transfer device 118 or the pod shelf 105. In a front region of the transfer chamber 124, a wafer transfer mechanism 125 is installed. The wafer transfer mechanism 125 includes a wafer transfer device 125a which can rotate or linearly move the wafer 200 in a horizontal direction, and a wafer transfer device elevator 125b which elevates the wafer transfer device 125a. As schematically illustrated in FIG. 1, the wafer transfer device elevator (not illustrated) is installed between a right end portion of a pressure-resistant housing 111 and a right end portion of the front region of the transfer chamber 124 of the sub-housing 119. Due to a continuous operation of the wafer transfer device elevator 125b and the wafer transfer device 125a, tweezers (substrate holder) 125c of the wafer transfer device 125a are configured as a placement portion of the wafer 200 such that the wafer 200 is charged and discharged with respect to a boat (substrate holding tool) 217.

In a rear region of the transfer chamber 124, a standby portion 126 is configured to accommodate the boat 217 and make the boat 217 stand by. Above the standby portion 126, a processing furnace 202 used as a processing chamber is provided. A lower end portion of the processing furnace 202 is configured to be opened and closed by a furnace port shutter 147.

As schematically illustrated in FIG. 1, a boat elevator 115 for elevating the boat 217 is installed between the right end portion of the pressure-resistant housing 111 and the right end portion of the standby portion 126 of the sub-housing 119. A seal cap 219 as a lid is configured to be horizontally mounted in an arm 128 as a connecting tool connected to an elevation table of the boat elevator 115, and the seal cap 219 is configured to vertically support the boat 217 and close the lower end portion of the processing furnace 202.

The boat 217 includes a plurality of holding members and is configured to horizontally hold a plurality of wafers 200 (for examples, 50 to 125 wafers) in a state of being arranged in a vertical direction, with the centers of the wafers 200 being aligned.

As schematically illustrated in FIG. 1, a clean unit 134 is provided in the left end portion being an opposite side of the boat elevator 115 side and the wafer transfer device elevator 125b side of the transfer chamber 124. The clean unit 134 includes a supply fan and a dust-proof filter and supplies clean air 133 that is a cleaned atmosphere or inert gas. Although not illustrated, a notch alignment device is installed between the wafer transfer device 125a and the clean unit 134 as a substrate alignment device which aligns positions of the wafers in a circumferential direction. The clean air 133 blown from the clean unit 134 circulates through the notch alignment device 135, the wafer transfer device 125a, and the boat 217 of the standby portion 126, is suctioned by a duct (not illustrated), and is exhausted to the outside of the housing 111, or circulates to a primary side (supply side) being a suction side of the clean unit 134 and is blown into the transfer chamber 124 again by the clean unit 134.

Next, the operation of the substrate processing apparatus 100 will be described with reference to FIGS. 1 to 3. In the following description, the operations of the respective components constituting the substrate processing apparatus 100 are controlled by a controller 240. The configuration of the controller 240 is illustrated in FIG. 3. The controller 240 controls the pod transfer device 118, the pod shelf 105, the wafer transfer mechanism 125, the boat elevator 115, and the like through an input/output device 241. As illustrated in FIGS. 1 and 2, when the pod 110 is supplied to the load port 114, the pod carrying-in/carrying-out port 112 is opened by the front shutter 113, and the pod 110 on the load port 114 is carried in from the pod carrying-in/carrying-out port 112 to the inside of the housing 111 by the pod transfer device 118. The carried-in pod 110 is automatically transferred and delivered to the designated placement portion 117 of the pod shelf 105 by the pod transfer device 118 and is temporarily stored. Then, the pod 110 is transferred and delivered from the pod shelf 105 to one pod opener 121 and is temporarily stored. Then, the pod 110 is transferred from the pod shelf 105 to one pod opener 121 and is delivered on the placement table 122, or is directly transferred to the pod opener 121 and is delivered on the placement table 122. At this time, the wafer carrying-in/carrying-out port 120 of the pod opener 121 is closed by the cap attaching/detaching mechanism 123, and the clean air 133 is circulated and filled in the transfer chamber 124. For example, the transfer chamber 124 is filled with a nitrogen gas as the clean air 133, and an oxygen concentration is 20 ppm or less, which is much lower than an oxygen concentration of the inside of the housing 111 (ambient atmosphere).

An opening-side end surface of the pod 110 placed on the placement table 122 is pressed against an opening edge portion of the wafer carrying-in/carrying-out port 120 in the front wall 119a of the sub-housing 119, and the cap of the pod 110 is detached by the cap attaching/detaching mechanism 123 to open the wafer loading/unloading port. When the pod 110 is opened by the pod opener 121, the wafer 200 is picked up from the pod 110 through the wafer loading/unloading port by the tweezers 125c of the wafer transfer device 125a. After the wafer 200 is aligned by the notch alignment device 135, the wafer is carried in to the standby portion 126 in the rear side of the transfer chamber 124 and is charged in the boat 217. The wafer transfer device 125a which has delivered the wafer 200 to the boat 217 is returned to the pod 110 and charges a next wafer 200 in the boat 217.

During the operation of charging the wafer to the boat 217 by the wafer transfer mechanism 125 in one pod opener 121 (upper stage or lower stage), another pod 110 is transferred and delivered by the pod transfer device 118 from the pod shelf 105 to the other pod opener 121 (lower stage or upper stage). The operation of opening the pod 110 by the pod opener 121 is simultaneously performed.

When a previously designated number of wafers 200 are charged into the boat 217, the lower end portion of the processing furnace 202, which has been closed by the furnace port shutter 147, is opened by the furnace port shutter 147. Subsequently, the boat 217 holding a group of the wafers 200 is carried in (loaded) to the inside of the processing furnace 202 when the seal cap 219 moves upward by the boat elevator 115.

After the loading, any processing is performed on the wafer 200 in the processing furnace 202. After the processing, except for a wafer matching process in the notch alignment device 135 (not illustrated), the wafer 200 and the pod 110 are delivered in an order reverse to the above description.

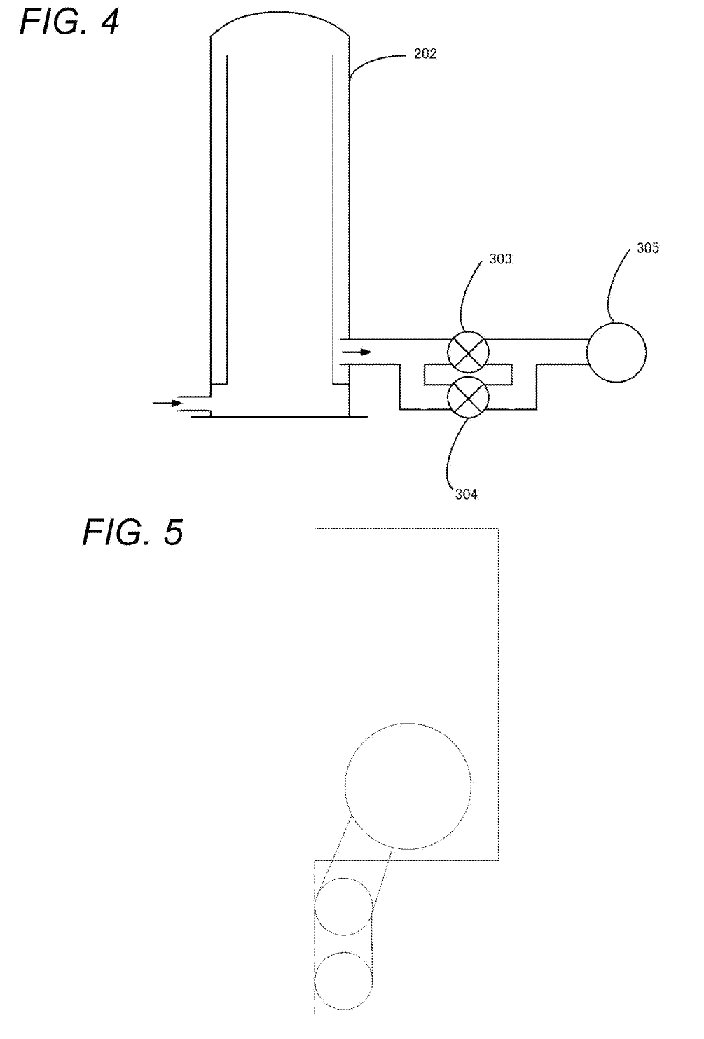

Next, an exhaust system according to the present invention will be described with reference to FIGS. 4 to 6. FIG. 4 is a schematic longitudinal sectional view of the substrate processing apparatus according to the embodiment of the present invention, and FIG. 5 is a schematic horizontal sectional view of the substrate processing apparatus according to the embodiment of the present invention.

In the embodiment illustrated in FIG. 4, a film-forming gas or a doping gas, a processing gas such as an etching gas, a purge gas such as an inert gas, or a mixed gas thereof is supplied into the reaction tube 202 from a gas supply unit 401 passing through the reaction tube 202 (or a support member such as a manifold (not illustrated) which supports the reaction tube). In the embodiment of the present invention, an exhaust pipe is connected to the reaction tube 202 (or the support member such as a manifold (not illustrated) which supports the reaction tube), and the exhaust pipe is configured to become two systems in the same conductance (exhaust amount) at a downstream side of the connection portion with the reaction tube 202. A variable valve (for example, APC valve or the like, and hereinafter described as APC valve being used) 303 which can control a valve opening degree so as to adjust the exhaust amount by the controller 240 is provided in one exhaust pipe. A fixed valve (hereinafter described as ON/OFF valve) 304 which can control only the ON/OFF switching is provided in parallel in the other exhaust pipe. In this way, the exhaust amount in the processing furnace 202 is controlled. In the embodiment of the present invention, the exhaust pipes which are divided into two systems are merged in the downstream and are connected to an exhaust pump 305. As illustrated in FIG. 5, this configuration makes it possible to increase the exhaust amount without greatly increasing the footprint.

Here, in the embodiment of the present invention, the exhaust system, that is, the exhaust line (exhaust part), is configured by the exhaust pipe, the APC valve 303, the ON/OFF valve 304, a pressure sensor (not illustrated), and the like. When necessary, the exhaust pump 305, a trap device (not illustrated) or a damage prevention device (not illustrated) may be included in the exhaust system.

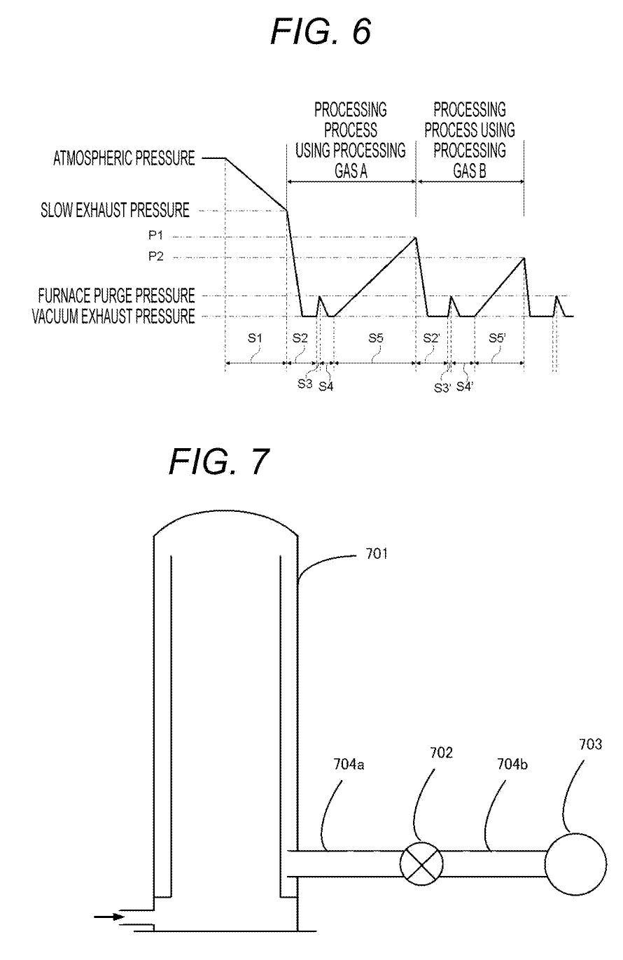

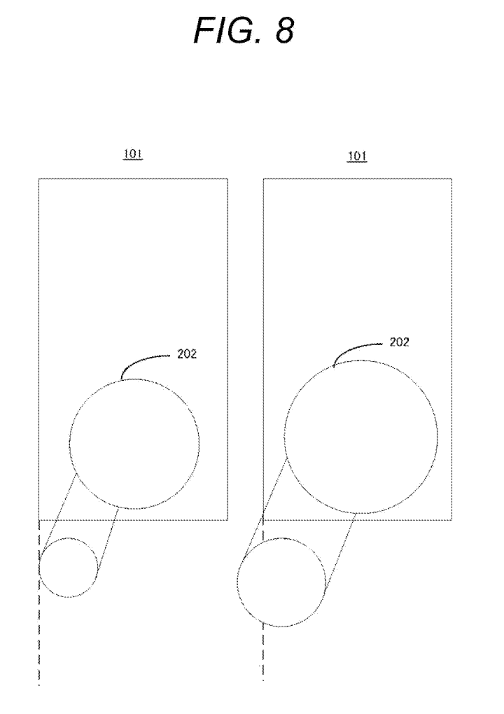

Next, an exhaust control method performed using the substrate processing apparatus according to the embodiment of the present invention will be described in detail with reference to FIG. 6. FIG. 6 is a diagram illustrating an example of a process event according to an embodiment of the present invention.

In FIG. 6, a vertical direction represents a pressure inside the reaction tube, and a horizontal direction represents the elapse of time. In the embodiment of the present invention, a process of forming a film by using two types of processing gas with different processing pressures during a deposition process for depositing a desired film will be described.

As described above, when the boat 217 carrying the wafer 200 is loaded into the processing furnace 202, it is necessary to reduce a pressure from the atmospheric pressure to a desired pressure by evacuating the processing furnace 202. At this time, when a large amount of exhaust is rapidly performed by fully opening the APC valve 303 and the ON/OFF valve 304 being the exhaust valves, a load may be applied to the valves or the exhaust pump 305 and each component may be damaged. Therefore, during a predetermined period, the controller 240 performs control such that the APC valve 303 is opened to a predetermined opening degree while the ON/OFF valve is closed. Due to such a control, the processing furnace is slowly exhausted (slow exhaust) (S1).

After the slow exhaust is performed for the previously determined time, or after the pressure is reduced to a desired slow exhaust pressure, the exhaust is performed at a maximum exhaust amount by opening the ON/OFF valve 304 while fully opening the valve opening degree of the APC valve 303 until a desired vacuum exhaust pressure is achieved (S2). At this time, as illustrated in FIG. 6, the control may be performed such that when the pressure becomes the desired vacuum exhaust pressure, that pressure is maintained (S2).

When the processing furnace has the desired vacuum exhaust pressure, a furnace purge is performed by supplying an inert gas such as N₂ so as to clean the furnace (S3). At this time, in order to maintain a furnace purge pressure, the pressure control is performed by closing the ON/OFF valve 304 and controlling the opening degree of the APC valve 303 through the controller 240.

After the furnace purge is performed for the previously determined time, the purge gas is completely exhausted (S4), and then, a processing gas A is supplied (S5). In order to maintain the processing pressure P1 during the supply of the processing gas A, the pressure control is performed by closing the ON/OFF valve 304 and controlling the opening degree of the APC valve 303 through the controller 240. At this time, as illustrated in FIG. 6, the control may be performed such that when the pressure becomes the desired vacuum exhaust pressure, that pressure is maintained (S4).

When the processing process using the processing gas A is completed, a processing process using a processing gas B is performed.

After the supply of the processing gas A, in order to exhaust the processing gas A, the exhaust is performed at a maximum exhaust amount by opening the ON/OFF valve 304 while fully opening the valve opening degree of the APC valve 303 until a desired vacuum exhaust pressure is achieved (S2′).

When the processing furnace has a predetermined vacuum exhaust pressure, a furnace purge is performed by supplying an inert gas such as N₂ so as to clean the furnace (S3′). At this time, in order to maintain a furnace purge pressure, the pressure control is performed by closing the ON/OFF valve 304 and controlling the opening degree of the APC valve 303 through the controller 240.

After the furnace purge is performed for the previously determined time, the purge gas is completely exhausted (S4′), and then, a processing gas B is supplied (S5′). In order to maintain the processing pressure P2 during the supply of the processing gas B, the pressure control is performed by closing the ON/OFF valve 304 and controlling the opening degree of the APC valve 303 through the controller 240. By performing these operations S2 to S5′ once or more, it is possible to form a film or a stacked film such as a laminated structure having a desired thickness.

Hereinafter, the sequence of the present embodiment will be described in detail. Here, when assuming that the processing gas A is a titanium (Ti)-containing gas and the processing gas B is a nitrogen-containing gas, a processing process of forming a titanium nitride film (TiN film) by using these gas will be described as an example.

As the titanium-containing gas, for example, titanium tetrachloride (TiCl₄) or tetrakis dimethyl amino titanium (Ti[N(CH₃)₂]₄, abbreviation: TDMAT) may be used. As the nitrogen-containing gas, gas obtained by exciting an N₂ gas, an NF₃ gas, and an N₃H₈ gas by plasma or heat as well as gas obtained by exciting an NH₃ gas by plasma or heat may be used. Gas obtained by diluting these gas with a rare gas such as argon (Ar), helium (He), neon (Ne), or xenon (Xe) gas may be excited by plasma or heat and used.

When the plurality of wafers 200 is charged into the boat 217 (wafer charging), as illustrated in FIG. 1, the boat 217 supporting the plurality of wafers 200 is lifted by the boat elevator 115 and is loaded into the processing chamber (reaction chamber) of the reaction tube 202 (boat loading). In this state, the seal cap 219 is in a state of sealing the lower end portion of the reaction tube 202 through an O-ring 220.

The processing furnace is evacuated by the vacuum pump 305 such that the inside of the processing furnace has a desired pressure (vacuum degree). At this time, the pressure inside the processing furnace is measured by a pressure sensor (not illustrated). The processing furnace is slowly exhausted by a feedback control performed by the controller 240 such that the ON/OFF valve 304 is in an OFF state for a predetermined time and the APC valve 303 is opened to a predetermined opening degree, based on the measured pressure (S2).

When it is detected by the pressure sensor that the pressure inside the processing furnace is reduced to the desired pressure by the slow exhaust, the controller 240 controls the APC valve 303 and the ON/OFF valve 304 such that the opening degree of the APC valve 303 is fully opened to the maximum exhaust amount and the ON/OFF valve 304 is opened.

(Furnace Purge Process S3)

When the processing furnace has the desired pressure (vacuum exhaust pressure), the furnace purge is performed by supplying an inert gas such as N₂ gas, which is a purge gas for cleaning the furnace (S3). At this time, the controller 240 performs the pressure control by closing the ON/OFF valve 304 and controlling the opening degree of the APC valve 303, so that the pressure inside the furnace becomes the purge pressure.

(Processing Gas A Supply Process S5)

After the furnace purge is performed for the previously determined time, the controller 240 stops supplying the inert gas and controls the opening degree of the APC valve 303 to completely exhaust the insert gas supplied to the processing furnace (S4). After that, the titanium-containing gas, which is the processing gas A, is supplied (S5). At this time, the inside of the processing chamber 201 is heated by a heater (not illustrated) to be a desired temperature. At this time, the energization state of the heater is feedback-controlled based on temperature information detected by a temperature sensor (not illustrated), such that the inside of the processing chamber 201 has a desired temperature distribution (temperature adjustment). The wafer 200 is rotated by the rotation of the boat 217 by a rotation mechanism (not illustrated) (wafer rotation).

In the processing furnace 202, the titanium-containing gas is supplied to the wafer 200 for a predetermined time. The controller 240 controls the APC valve 303 and the ON/OFF valve 304 such that the processing furnace 202 has a predetermined processing pressure P1 (for example, the controller 240 performs control such that both of the APC valve 303 and the ON/OFF valve 304 are closed, or only the APC valve 303 is opened to a predetermined opening degree). By supplying the titanium-containing gas, the titanium-containing gas contacts the surface of the wafer 200 to form a titanium-containing layer as a “first element-containing layer” on the surface of the wafer 200. The titanium-containing layer is formed to have a predetermined thickness and a predetermined distribution according to, for example, the pressure inside the processing furnace 202, the flow rate of the titanium-containing gas, and the processing time in the processing furnace 202. After the elapse of a predetermined time, the controller 240 stops supplying the titanium-containing gas.

(Processing Gas A Exhaust Process S2′)

After the supply of the titanium-containing gas is stopped, the controller 240 performs control such that the titanium-containing gas existing within the processing furnace 202 is exhausted by fully opening the APC valve 303 and opening the ON/OFF valve 304, and the processing furnace 202 has a desired pressure (vacuum exhaust pressure) (S2′).

(Furnace Purge Process S3′)

When the processing furnace has the desired pressure (vacuum exhaust pressure), the furnace purge is performed by supplying an inert gas such as N₂ gas, which is a purge gas for cleaning the furnace (S3′). At this time, the controller 240 performs the pressure control by closing the ON/OFF valve 304 and controlling the opening degree of the APC valve 303, so that the pressure inside the furnace becomes the purge pressure.

(Processing Gas B Supply Process S5′)

After the furnace purge is performed for the previously determined time, the controller 240 stops supplying the inert gas and controls the opening degree of the APC valve 303 to completely exhaust the insert gas supplied to the processing furnace (S4′). After that, the nitrogen-containing gas, which is the processing gas B, is supplied (S5′).

In the processing furnace 202, the nitrogen-containing gas excited by plasma or heat is supplied on the wafer 200 for a predetermined time. The titanium-containing layer already formed on the wafer 200 is modified by the excited nitrogen-containing gas, thereby forming a TiN layer containing the titanium element and the nitrogen element on the wafer 200.

The modified layer containing the titanium element and the nitrogen element is formed to have a predetermined thickness, a predetermined distribution, and a penetration depth of a predetermined nitrogen component with respect to the titanium-containing layer, for example, according to the pressure inside the processing furnace 202, the flow rate of the excited nitrogen-containing gas, or the like. After the elapse of a predetermined time, the controller 240 stops supplying the nitrogen-containing gas.

(Processing Gas B Exhaust Process)

After the supply of the nitrogen-containing gas is stopped, the controller 240 performs control such that the nitrogen-containing gas existing within the processing furnace 202 is exhausted by fully opening the APC valve 303 and opening the ON/OFF valve 304, and the processing furnace 202 has a desired pressure (vacuum exhaust pressure).

By performing these operations S2 to S5′ once or more, it is possible to form a TiN film having a desired thickness.

As described above, according to the present invention, since it is unnecessary to increase the diameter of the exhaust pipe or increase the size of the exhaust valve, it is possible to achieve the effect that can perform the same pressure control as the related art while suppressing an increase in the footprint.

In addition, as described above, the embodiment of the present invention has been specifically described, but the present invention is not limited to the above-described embodiment. Various modifications can be made without departing from the scope of the present invention and the effects can also be achieved according to the modifications.

For example, in the above-described embodiment of the present invention, in the furnace purge processes S3 and S3′ and the processing gas A and processing gas B supply processes S5 and S5′, the pressure inside the furnace is controlled by closing the ON/OFF valve 304 and controlling the opening degree of the APC valve 303, but the present invention is not limited thereto. The control may be performed to maintain the pressure inside the furnace by closing both the APC valve 303 and the ON/OFF valve 304. In addition, when the control of the pressure inside the furnace, for a cleaning process or the like other than above-described processes, is required, the pressure control may be performed using the APC valve 303. Furthermore, when an exhaust, in which the control of the pressure inside the furnace is unnecessary, for a vacuum exhaust process or the like other than the above-described processes, is required, the ON/OFF valve 304 may be used.

In addition, in the above-described embodiment of the present invention, it has been described that one of at least two valves provided in the exhaust pipe is the APC valve, and the other valve is the valve that can control only the ON-OFF switching, but the present invention is not limited thereto. Both valves may use the APC valves that can control the valve opening degree. Furthermore, the type of the valve is not limited to the APC valve. Any variable valve may be used as long as the valve opening degree of the valve can be controlled by the controller and the valve can change the conductance.

In addition, in the above-described embodiment of the present invention, it has been described that the exhaust amount when the opening degree of the APC valve is maximum and the exhaust amount when the ON-OFF valve is opened are provided to be equal to each other, but the present invention is not limited thereto. The exhaust amount when the opening degree of the APC valve is maximum and the exhaust amount when the ON-OFF valve is opened may be different from each other. For example, the exhaust amount when the ON-OFF valve is opened may be larger than the exhaust amount when the opening degree of the APC valve is maximum. The exhaust amount when the ON-OFF valve is opened may be smaller than the exhaust amount when the opening degree of the APC valve is maximum.

In addition, in the above-described embodiment of the present invention, the process of forming the titanium nitride film (TiN film) by using the titanium (Ti)-containing gas as the processing gas A and the nitrogen-containing gas as the processing gas B. However, a silicon nitride film (SiN film) may be formed by using silicon (Si)-containing gas as the processing gas A and a nitrogen-containing gas as the processing gas B. A silicon oxide film (SiO film) may be formed by using silicon-containing gas as the processing gas A and an oxygen-containing gas as the processing gas B. An aluminum nitride film (AlN film) may be formed by using aluminum (Al)-containing gas as the processing gas A and a nitrogen-containing gas as the processing gas B. An aluminum oxide film (AlO film) may be formed by using aluminum (Al)-containing gas as the processing gas A and an oxygen-containing gas as the processing gas B. In this case, as the silicon-containing gas, for example, organic raw materials, such as aminosilane-based tetrakis dimethyl amino silane (Si(N(CH₃)₂))₄, abbreviation: 4DMAS) gas, trisdimethylaminosilane (Si(N(CH₃)₂))₃H, abbreviation: 3DMAS) gas, bis diethylaminosilane (Si(N(C₂H₅)₂)₂H₂, abbreviation: 2DEAS) gas, bis-tertiary-butyl-amino-silane (SiH₂(NH(C₄H₉))₂, abbreviation: BTBAS) gas, as well as inorganic raw materials, such as dichlorosilane (SiH₂Cl₂, abbreviation: DCS) gas, tetrachlorosilane (SiCl₄, abbreviation: TCS) gas, hexachlorodisilane (Si₂Cl₆, abbreviation: HCD) gas, and monosilane (SiH₄) gas can be used. As the oxygen-containing gas, for example, oxygen (O₂) gas, ozone (O₃) gas, nitric oxide (NO) gas, nitrous oxide (N₂O) gas, and water vapor (H₂O) can be used. As the aluminum-containing gas, for example, trimethylaluminum (Al(CH₃)₃, abbreviated: TMA) can be used.

In addition, in the above-described embodiment of the present invention, the processing process using the processing gas A and the processing gas B has been described, but the present invention is not limited thereto. The processing processes S2 to S5 using only the processing gas A may be repeatedly performed.

As the substrate processing apparatus 101, the semiconductor manufacturing apparatus is configured to perform the method of manufacturing the semiconductor device (IC), but the present invention can also be applied to an apparatus for processing a glass substrate, such as an LCD device, as well as the semiconductor manufacturing apparatus.

Examples of the film-forming process performed by the substrate processing apparatus 101 include a CVD, a PVD, an ALD, an Epi, a process of forming an oxide film or a nitride film, and a process of forming a metal-containing film. Furthermore, the film-forming process may include an annealing processing, an oxidation process, a diffusion process, and the like.

In addition, in the present embodiment, the substrate processing apparatus is described as the vertical processing apparatus 101, but the present invention can be equally applied to a single-wafer type device. Furthermore, the present invention can be equally applied to an etching apparatus, an exposure apparatus, a lithography apparatus, a deposition apparatus, a molding apparatus, a development apparatus, a dicing apparatus, a wire bonding apparatus, an inspection apparatus, and the like.

<Preferred Aspects of Present Invention>

Hereinafter, preferred aspects of the present invention will be additionally described.

(Supplementary Note 1)

A substrate processing apparatus including: a reaction tube configured to process substrates by carrying in a substrate holder holding a plurality of substrates; a gas supply unit configured to supply a processing gas into the reaction tube; an exhaust unit including at least two exhaust pipes configured to exhaust gas supplied by the gas supply unit, and valves provided in the at least two exhaust pipes to control exhaust amount of the at least two exhaust pipes; and a control unit configured to control the valves provided in the exhaust unit at a predetermined timing.

(Supplementary Note 2)

The substrate processing apparatus as described in Supplementary Note 1, in which the valves include at least one variable valve configured to adjust exhaust amount according to the control of the control unit.

(Supplementary Note 3)

The substrate processing apparatus as described in Supplementary Note 2, in which the control unit adjusts the pressure inside the reaction tube to a second pressure by controlling the at least one variable valve and closing the other valves until the pressure inside the reaction tube changes from an atmospheric pressure to a first pressure and opening all of the other closed valves and the variable valves when the pressure inside the reaction tube reaches the first pressure; adjusts the pressure inside the reaction tube to a third pressure by controlling the at least one variable valve and closing the other valves during the process of cleaning the reaction tube; adjusts the pressure inside the reaction tube to the second pressure by opening all of the at least one variable valve and the other valves after the cleaning process; and controls the gas supply unit to supply the processing gas to the reaction tube after the pressure inside the reaction tube reaches the second pressure.

(Supplementary Note 4)

A method of manufacturing a semiconductor device including: carrying in a substrate holder holding a substrate into a reaction tube; supplying a processing gas from a gas supply unit into the reaction tube; after the process of supplying the processing gas, exhausting the processing gas by an exhaust unit, the exhaust unit including at least two exhaust pipes and at least two valves provided in the at least two exhaust pipes so as to control exhaust amount of the at least two exhaust pipes; and controlling the at least two valves provided in the exhaust unit at a predetermined timing.

(Supplementary Note 5)

A method of manufacturing a semiconductor device including: carrying in a substrate holder holding a of substrate into a reaction tube; at least two exhaust pipes connected to the reaction tube to exhaust an atmosphere in the reaction tube and valves connected to the exhaust pipe, at least one of which is a variable valve capable of changing an exhaust amount being provided, exhausting the reaction tube from an atmospheric pressure to a first pressure by controlling the variable valve; after the pressure inside the reaction tube is exhausted from the atmospheric pressure to the first pressure, exhausting the reaction tube to a second pressure by opening all of the variable valve and the other valves; after the process of exhausting to the second pressure, purging the inside of the reaction tube by supplying a purge gas by a gas supply unit provided in the reaction tube; after the supply of the purge gas, exhausting the reaction tube again to the second pressure by opening all of the variable valve and the other valves; and after the pressure inside the reaction tube reaches the second pressure again, forming a desired film by supplying the processing gas by the gas supply unit.

(Supplementary Note 6)

The substrate processing method including: carrying in a substrate holder holding a substrate into a reaction tube; supplying a processing gas from a gas supply unit into the reaction tube; and after the process of supplying the processing gas, controlling at least two exhaust pipes and at least two valves for adjusting exhaust amount of the exhaust pipes at a predetermined timing.

(Supplementary Note 7)

A substrate processing method including: carrying in a substrate holder holding a substrate into a reaction tube; supplying a processing gas from a gas supply unit into the reaction tube; at least two exhaust pipes connected to the reaction tube to exhaust an atmosphere in the reaction tube and valves connected to the exhaust pipe, at least one of which is a variable valve capable of changing an exhaust amount being provided, exhausting the reaction tube from an atmospheric pressure to a first pressure by controlling the variable valve; after the pressure inside the reaction tube is exhausted from the atmospheric pressure to the first pressure, exhausting the reaction tube to a second pressure by opening all of the variable valve and the other valves; after the process of exhausting to the second pressure, purging the reaction tube by supplying a purge gas by a gas supply unit provided in the reaction tube; after the supply of the purge gas, exhausting the reaction tube again to the second pressure by opening all of the variable valve and the other valves; and after the pressure inside the reaction tube reaches the second pressure again, forming a desired film by supplying the processing gas by the gas supply unit.

### INDUSTRIAL APPLICABILITY

As described above, the present invention can be used in a substrate processing apparatus, a method of manufacturing a semiconductor device, and a substrate processing method, which are capable of performing an exhaust pressure control of processing gas in association with an increase in the diameter of a substrate to be processed by a simple configuration.

### REFERENCE SIGNS LIST

101 substrate processing apparatus
110 pod
124 transfer chamber
200 wafer (substrate)
202 reaction tube
217 boat
240 controller
303 APC valve (variable valve)
304 valve (ON/OFF valve)
401 gas supply unit

1. A substrate processing apparatus comprising:
a reaction tube configured to process a plurality of substrates carried in a substrate holder;
a gas supply unit configured to supply a processing gas into the reaction tube;
an exhaust unit connected to the reaction tube and branching into at least two exhaust pipes at a downstream side of a connection portion with the reaction tube, the exhaust unit including a valve configured to control the amount of the exhaust in exhaust pipes, and merged into one exhaust pipe downstream of valves provided in the exhaust pipes; and
a control unit configured to fully open all the valves provided in the exhaust unit at a timing to substantially evacuate the reaction tube.

2. The substrate processing apparatus according to claim 1, wherein at least one of the valves is a variable valve for adjusting the valve opening degree by control of the control unit, and the valves other than the variable valve are ON/OFF valves configured to perform only an ON/OFF operation.

3. The substrate processing apparatus according to claim 2, wherein the exhaust pipes in which the variable valve and the ON/OFF valves are provided are configured to have the same conductance.

4. A method of manufacturing a semiconductor device, comprising:
carrying a substrate in a substrate holder into a reaction tube;
supplying a processing gas from a gas supply unit into the reaction tube; and
after the process of supplying the processing gas, exhausting an atmosphere inside the reaction tube by fully opening all valves provided in an exhaust unit, the exhaust unit being connected to the reaction tube and branching into at least two exhaust pipes at a downstream side of a connection portion with the reaction tube, the exhaust unit including a valve configured to control the amount of exhaust in the exhaust pipes, and merged into one exhaust pipe downstream of valves provided in the exhaust pipes.

5. The method of manufacturing a semiconductor device according to claim 4, wherein at least one of the valves is a variable valve whose valve opening degree is adjusted by the control unit, and the valves other than the variable valve are ON/OFF valves configured to perform only an ON/OFF operation

6. The method of manufacturing a semiconductor device according to claim 5, wherein the exhaust pipes in which the variable valve and the ON/OFF valves are provided are configured to have the same conductance.

7. The method of manufacturing a semiconductor device according to claim 5, further comprising, after the process of carrying the substrate in the substrate holder into the reaction tube:
reducing a pressure inside the reaction tube from an atmospheric pressure to a first pressure by opening the variable valve to a predetermined opening degree; and
reducing the pressure from the first pressure to a second pressure, which is a pressure when the reaction tube is evacuated, by opening both the variable valve and the ON/OFF valves.

8. The method of manufacturing a semiconductor device according to claim 5, wherein in the process of supplying the processing gas, the control is performed such that the variable valve is opened to a predetermined opening degree and the ON/OFF valves are closed.

9. A substrate processing method comprising:
carrying a substrate in a substrate holder into a reaction tube;
supplying a processing gas from a gas supply unit into the reaction tube; and
after the process of supplying the processing gas, exhausting an atmosphere inside the reaction tube by fully opening all valves provided in an exhaust unit, the exhaust unit being connected to the reaction tube and branching into at least two exhaust pipes at a downstream side of a connection portion with the reaction tube, the exhaust unit including a valve configured to control the amount of exhaust in the exhaust pipes, and merged into one exhaust pipe downstream of valves provided in the exhaust pipes.

10. The substrate processing method according to according to claim 9, wherein at least one of the valves is a variable valve whose valve opening degree is adjusted by the control unit, and the valves other than the variable valve are ON/OFF valves configured to perform only an ON/OFF operation.

11. The substrate processing method according to claim 10, wherein the exhaust pipes in which the variable valve and the ON/OFF valves are provided are configured to have the same conductance.

12. The substrate processing method according to claim 10, further comprising, after the process of carrying the substrate in the substrate holder into the reaction tube:
reducing a pressure inside the reaction tube from an atmospheric pressure to a first pressure by opening the variable valve to a predetermined opening degree; and
reducing the pressure from the first pressure to a second pressure, which is a pressure when the reaction tube is evacuated, by opening both the variable valve and the ON/OFF valves.

13. The substrate processing method according to claim 10, wherein in the process of supplying the processing gas, the control is performed such that the variable valve is opened to a predetermined opening degree and the ON/OFF valves are closed.
